(19) United States
(12) Patent Application Publication
(10) Pub. No.: US 2011/0291084 A1
(43) Pub. Date: Dec. 1, 2011

(54) Display Device and Backplane

(75) Inventors: Jeremy Burroughes, Cambridgeshire (GB); Stephen Coats, Cambridgeshire (GB); Haydn Gregory, Cambridge (GB); Euan Smith, Cambridgeshire (GB); Julian Carter, Cambridgeshire (GB)

(73) Assignee: CAMBRIDGE DISPLAY TECHNOLOGY LIMITED, Cambridgeshire (GB)

(21) Appl. No.: 13/123,862

(22) PCT Filed: Oct. 21, 2009
(86) PCT No.: PCT/GB09/02507

§ 371 Date: Aug. 18, 2011

(30) Foreign Application Priority Data
Oct. 23, 2008 (GB) 0819450.8
Jan. 15, 2009 (GB) 0900620.6

(51) Int. Cl. H01L 27/32; H01L 51/56

(52) U.S. Cl. 257/40; 438/35; 257/E27.119; 257/E51.022

(57) ABSTRACT

A display device comprises a plurality of electroluminescent display pixels and a plurality of semiconductor elements (“chiplets”), each pixel being electrically connected to the output of one or more of said semiconductor elements through a via hole in an electrically insulating layer for addressing the plurality of display pixels, and a plurality of colour filters and/or downconverters. The colour filters and/or downconverters and the semiconductor elements are provided on the same surface of the device.

The present invention relates to displays and active backplanes for use in displays. It relates particularly, though not exclusively to devices having electroluminescent organic or inorganic pixels. It also relates to a method of making such devices.

### BACKGROUND

Recent years have seen very substantial growth in the market for displays as the quality of displays improves, their cost falls, and the range of applications for displays increases. This includes both large area displays such as for TVs or computer monitors and smaller displays for portable devices.

The most common classes of display presently on the market are liquid crystal displays and plasma displays although displays based on organic light-emitting diodes (OLEDs) are now increasingly attracting attention due to their many advantages including low power consumption, light weight, wide viewing angle, excellent contrast and potential for flexible displays.

The basic structure of an OLED is a light emissive organic layer, for instance a film of a poly (p-phenylenevinylene) (“PPV”) or polyfluorene, sandwiched between a cathode for injecting negative charge carriers (electrons) and an anode for injecting positive charge carriers (holes) into the organic layer. The electrons and holes combine in the organic layer generating photons. In WO90/13148 the organic light-emissive material is a conjugated polymer. In U.S. Pat. No. 4,539,507 the organic light-emissive material is of the class known as small molecule materials, such as (8-hydroxyquinoline) aluminium (“Alq3”). In a practical device one of the electrodes is transparent, to allow the photons to escape the device.

A typical organic light-emissive device (“OLED”) is fabricated on a glass or plastic substrate coated with a transparent anode such as indium-tin-oxide (“ITO”). A layer of a thin film of at least one electroluminescent organic material covers the first electrode. Finally, a cathode covers the layer of electroluminescent organic material. The cathode is typically a metal or alloy and may comprise a single layer, such as aluminium, or a plurality of layers such as calcium and aluminium. In operation, holes are injected into the device through the anode and electrons are injected into the device through the cathode. The holes and electrons combine in the organic electroluminescent layer to form an exciton which then undergoes radiative decay to give light. The device may be pixellated with red, green and blue electroluminescent subpixels in order to provide a full colour display.

Full colour liquid crystal displays typically comprise a white-emitting backlight, and light emitted from the device is filtered through red, green and blue colour filters after passing through the LC layer to provide the desired colour image.

A full colour display may be made in the same way by using a white or blue OLED in combination with colour filters. Moreover, it has been demonstrated that use of colour filters with OLEDs may be beneficial even when the pixels of the device already comprise red, green and blue subpixels. In particular, aligning red colour filters with red electroluminescent subpixels and doing the same for green and blue subpixels and colour filters can improve colour purity of the display (for the avoidance of doubt, “pixel” as used herein may refer to a pixel that emits only a single colour or a pixel comprising a plurality of individually addressable subpixels that together enable the pixel to emit a range of colours).

Downconversion, by means of colour change media (CCMs) for absorption of emitted light and reemission at a desired longer wavelength or band of wavelengths, can be used as an alternative to, or in addition to, colour filters.

One way of addressing displays such as LCDs and OLEDs is by use of an “active matrix” arrangement in which individual pixel elements of a display are activated by an associated thin-film transistor. The active matrix backplane for such displays can be made with amorphous silicon (a-Si) or low temperature polysilicon (LTPS). LTPS has high mobility but can be non-uniform and requires high processing temperatures which limits the range of substrates that it can be used with. Amorphous silicon does not require such high processing temperatures, however its mobility is relatively low, and can suffer from non-uniformities during use due to aging effects. Moreover, backplanes formed from either LIPS or a-Si both require processing steps such as photolithography, cleaning and annealing that can damage the underlying substrate. In the case of LTPS, in particular, a substrate that is resistant to these high-energy processes must be selected. An alternative approach to patterning is disclosed in, for example, Rogers et al, Appl. Phys. Lett. 2004, 84(26), 5398-5400; Rogers et al Appl. Phys. Lett. 2006, 88, 213101- and Benkendorfer et al, Compound Semiconductor, June 2007, in which silicon on an insulator is patterned using conventional methods such as photolithography into a plurality of elements (hereinafter referred to as “chiplets”) which are then transferred to a device substrate. The transfer printing process takes place by bringing the plurality of chiplets into contact with an elastomeric stamp which has surface chemical functionality that causes the chiplets to bind to the stamp, and then transferring the chiplets to the device substrate. In this way, chiplets carrying micro- and nano-scale structures such as display driving circuitry can be transferred with good registration onto an end substrate which does not have to tolerate the demanding processes involved in silicon patterning.

However, in the case of displays this still leaves the problem that the backplane after planarization is relatively thick. Moreover, if a colour filter layer is to be used then a further layer and further thickness is added to the device.

### SUMMARY OF THE INVENTION

According to the present invention there is provided a display device as specified in the claims.

The present inventors have found that colour filters and/or downconverters and chiplets may be incorporated into a common layer. This reduces thickness and the number of layers in the device.

Accordingly, in a first aspect the invention provides a display device comprising a plurality of display pixels; a plurality of semiconductor elements for addressing the plurality of display pixels; and a plurality of colour filters and/or downconverters, wherein the colour filters and/or downconverters and the semiconductor elements are provided on the same surface of the device.

Each semiconductor element may comprise a single device such as a transistor or a plurality of devices, or indeed an entire driver circuit for addressing a given pixel.

Preferably, the plurality of semiconductor elements and colour filters and/or downconverters are covered by a layer of insulating material.

Suitable insulating materials include transparent insulating materials such as benzocyclobutane (BCB). Preferably, the insulating material has a transparency of at least 80% to light in the UV and visible wavelength range.

Preferably, the plurality of display pixels are provided over the layer of insulating material, each pixel being electrically connected to one or more of said semiconductor elements.

Preferably, the insulating layer comprises a plurality of conducting vias to provide the electrical connection between the display pixels an output of the semiconductor elements.

Preferably, the colour filters comprise red, green and blue colour filters and/or downconverters.

In one preferred embodiment, the display pixels are organic electroluminescent pixels, each comprising an anode, a cathode and an organic electroluminescent material between the anode and cathode.

Preferably, the display includes blue organic electroluminescent pixels. Preferably, the display pixels include red, green and blue organic electroluminescent subpixels.

In another preferred embodiment, the display pixels comprise a layer of liquid crystal material between two electrodes and a light source for illuminating the display pixels. Preferably, the light source in this embodiment is a white light source.

In a second aspect, the invention provides a method of forming a display device comprising the steps of: providing a display substrate comprising a plurality of semiconductor elements and a plurality of colour filters and/or downconverters on the same surface of the display substrate; and electrically connecting a plurality of display pixels to said plurality of semiconductor elements.

Preferably, the method further comprising the step of covering the semiconductor elements and colour filters and/or downconverters with an insulating material and providing the plurality of display pixels over the insulating material.

Preferably, the colour filters are formed by inkjet printing.

Preferably, the plurality of semiconductor elements are formed by transfer printing the elements from a donor substrate to the display substrate.

It will be appreciated that the colour filters and/or downconverters are printed into spaces on the substrate that remain after printing of the semiconductor elements (or vice-versa, in the case where the semiconductor elements are printed first.)

Preferably, the plurality of semiconductor elements on the donor substrate are reversibly bonded to an elastomeric stamp and transferred to the display substrate.

In a third aspect the invention provides a backplane for a display comprising a substrate having a plurality of semiconductor elements and a plurality of colour filters and/or downconverters on the same surface of the substrate.

### DETAILED DESCRIPTION OF THE INVENTION

The invention will now be described in more detail with reference to the figures wherein:

FIG. 1 illustrates an OLED;

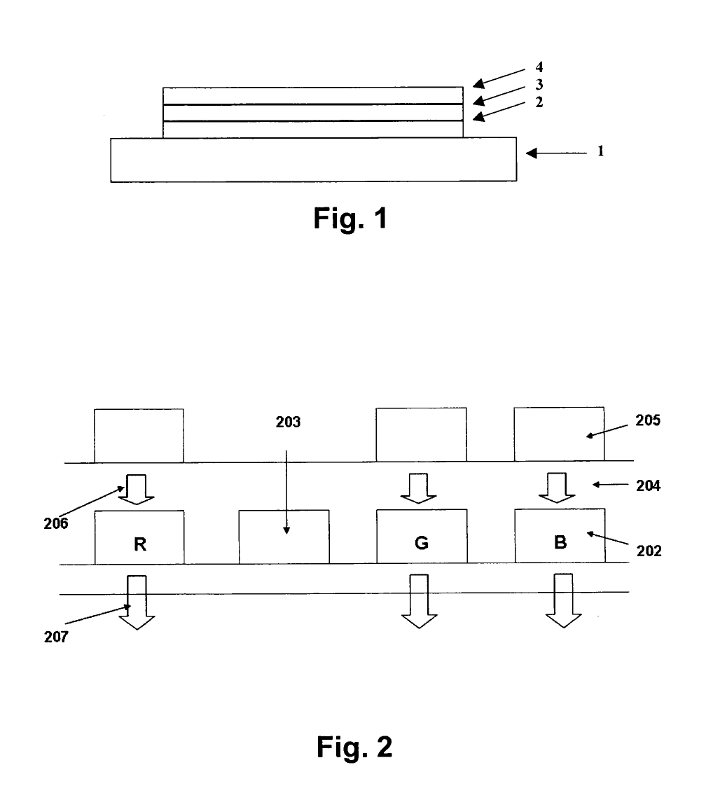

FIG. 2 illustrates a partial cross-section view of a light-emitting display device of the present invention; and

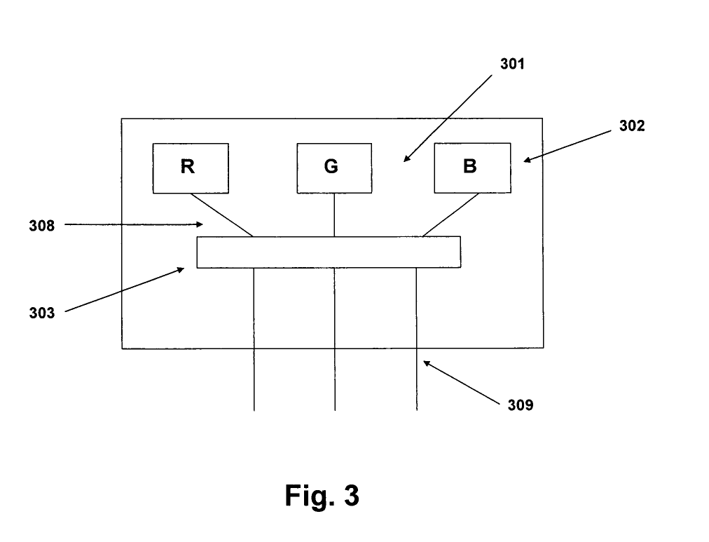

FIG. 3 illustrates a plan view of a backplane of the present invention.

### CHIPLET MATERIAL

The semiconductor elements (“chiplets”) may be formed from semiconductor wafer sources, including bulk semiconductor wafers such as single crystalline silicon wafers, polycrystalline silicon wafers, ultra thin semiconductor wafers such as ultra thin silicon wafers; doped semiconductor wafers such as p-type or n-type doped wafers and wafers with selected spatial distributions of dopants (semiconductor on insulator wafers such as silicon on insulator (e.g. Si—SiO2, SiGe); and semiconductor on substrate wafers such as silicon on substrate wafers and silicon on insulator. In addition, printable semiconductor elements of the present invention may be fabricated from a variety of nonwafer sources, such as a thin films of amorphous, polycrystalline and single crystal semiconductor materials (e.g. polycrystalline silicon, amorphous silicon) that is deposited on a sacrificial layer or substrate (e.g. SiN or SiO2) and subsequently annealed.

The chiplets may be formed by conventional processing means known to the skilled person.

Preferably, each driver or LED chiplet is up to 500 microns in length, preferably between about 15-250 microns, and preferably about 5-50 microns in width, more preferably 5-10 microns.

### Transfer Process

The stamp used in transfer printing is preferably a PDMS stamp.

The surface of the stamp may have a chemical functionality that causes the chiplets to reversibly bind to the stamp and lift off the donor substrate, or may bind by virtue of, for example, van der Waals force. Likewise upon transfer to the end substrate, the chiplets adhere to the end substrate by van der Waals force and/or by an interaction with a chemical functionality on the surface of the end substrate, and as a result the stamp may be delaminated from the chiplets.

To ensure accurate transfer onto a prepared end substrate, the stamp and end substrate may be registered

### Chiplet and Display Integration

The chiplets patterned with drive circuitry for addressing pixels or subpixels of a display may be transfer-printed onto a substrate carrying tracking for connection of the chiplets to a power source and, if required, drivers outside the display area for programming the chiplets.

To ensure accurate transfer onto a prepared end substrate, the stamp and end substrate may be registered by means known to the skilled person, for example by providing alignment marks on the substrate.

Alternatively, tracking for connection of the chiplets may be applied after the chiplets have been transfer printed.

In the case where the chiplets drive a display such as an LCD or OLED display, the backplane comprising the chiplets is preferably coated with a layer of insulating material to form a planarisation layer onto which the display is constructed. Electrodes of the display device are connected to the output of the chiplets by means of conducting through-vias formed in the planarisation layer.

FIG. 2 illustrates this arrangement. Onto substrate 201, formed from glass or transparent plastic, is provided red, green and blue downconverters 202 and chiplet 203. The chiplet and downconverters are covered with a layer of planarising material 204 such as BOB to form a surface onto which blue-emitting organic LED pixels 205 are provided. Chiplets are connected to the anodes of the OLED pixels by means of conducting through-vias (not shown). Emission 206 from the OLEDs is absorbed and re-emitted as light output 207.

The blue downconverter may be dispensed with if the colour of emission 206 of the blue OLED pixel is suitable for a display.

In another embodiment, red, green and blue OLED subpixels are provided and the emission from these pixels is downconverted or filtered by respective red, green and blue downconverters or colour filters.

In addition to being deposited over the chiplets, a layer of planarising material may also be deposited on the substrate in which case the chiplets and colour filters and/or downconverters are formed on this layer of planarising material.

Preferably, each driver chiplet addresses a plurality of display pixels (or subpixels, in the case of a multicolour display), preferably at least 4 and more preferably at least 6 pixels. In one embodiment, the display is a full colour display and at least some chiplets each address a red, green and blue subpixel. Light emitted from the display is transmitted through the layer of chiplets and colour filters (or downconverters), and so it is preferable that the chiplets take up as little space as possible to minimise the amount of said emitted light that is absorbed before reaching the viewer. One way of doing this is to maximise the number of pixels or subpixels being driven by a given chiplet, although this has to be balanced against the complexity of routing connections from the chiplets which increases as the number of pixels per chiplet increases.

FIG. 3 illustrates a backplane in which substrate 301 carries chiplet 303 that drives red, green and blue OLED subpixels 302. The subpixels 302 are connected to the chiplet 303 by means of connections 308, and the chiplet is connected to programming means 309 (not shown). Emission from the pixels passes through underlying downconverters before exiting the device.

### Organic LED

In the case where the display is an OLED, and with reference to FIG. 1, the device according to the invention comprises a glass or plastic substrate 1 onto which the backplane (not shown) has been formed, an anode 2 and a cathode 4. An electroluminescent layer 3 is provided between anode 2 and cathode 4.

In a practical device, at least one of the electrodes is semi-transparent in order that light may be emitted. Where the anode is transparent, it typically comprises indium tin oxide.

Suitable materials for use in layer 3 include small molecule, polymeric and dendrimeric materials, and compositions thereof. Suitable electroluminescent polymers for use in layer 3 include poly(arylene vinylenes) such as poly(p-phenylene vinylenes) and polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23) 1737-1750 and references therein. Suitable electroluminescent dendrimers for use in layer 3 include electroluminescent metal complexes bearing dendrimeric groups as disclosed in, for example, WO 02/066552.

Further layers may be located between anode 2 and cathode 3, such as charge transporting, charge injecting or charge blocking layers.

The device is preferably encapsulated with an encapsulant (not shown) to prevent ingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

The embodiment of FIG. 1 illustrates a device wherein the device is formed by firstly forming an anode on a substrate followed by deposition of an electroluminescent layer and a cathode, however it will be appreciated that the device of the invention could also be formed by firstly forming a cathode on a substrate followed by deposition of an electroluminescent layer and an anode.

Although the present invention has been described with reference to active backplane devices having organic electroluminescent pixels, the devices can also be formed from inorganic materials. Such devices and materials were described in the monograph “Light-emitting Diodes” by A. A. Bergh and P. J Dean, Clarendon Press, Oxford (1976) (ISBN 0198593171) and are well known to persons skilled in the art. The invention can also be used for displays which do not have electroluminescent pixels, such as for example liquid crystal displays.

1. A display device comprising a plurality of display pixels; a plurality of semiconductor elements for addressing the plurality of display pixels; and a plurality of color filters and/or downconverters, wherein the color filters and/or downconverters and the semiconductor elements are provided on the same surface of the device.

2. A display device as claimed in claim 1 in which the display pixels comprise light emitting devices.

3. A display device according to claim 1 in which the plurality of semiconductor elements and color filter elements and/or downconverters are covered by a layer of insulating material.

4. A display device according to claim 2 in which the plurality of display pixels are provided over the layer of insulating material, each pixel being electrically connected to one or more of said semiconductor elements.

5. A display device according to claim 4 in which the insulating layer comprises a plurality of conducting vias to provide the electrical connection between the display pixels an output of the semiconductor elements.

6. A display device according to claim 1 in which the color filters and/or downconverters comprise red, green, and blue color filters.

7. A display device according to claim 1 in which the display pixels are organic electroluminescent pixels, each comprising an anode, a cathode, and an organic electroluminescent material between the anode and cathode.

8. A display device according to claim 7 wherein the display includes blue organic electroluminescent pixels.

9. A display device according to claim 7 wherein the display pixels include red, green, and blue organic electroluminescent subpixels.

10. A display device according to claim 1 in which the display pixels comprise a layer of liquid crystal material between two electrodes, and a light source for illuminating the display pixels.

11. A method of forming a display device comprising the steps of providing a display substrate comprising a plurality of semiconductor elements and a plurality of color filters and/or downconverters on the same surface of the display substrate; and electrically connecting a plurality of display pixels to said plurality of semiconductor elements.

12. A method according to claim 11 further comprising the step of covering the semiconductor elements and color filters with an insulating material and providing the plurality of display pixels over the insulating material.

13. A method according to claim 11 wherein the color filters are formed by inkjet printing.

14. A method according to claim 11 wherein the plurality of semiconductor elements are formed by transfer printing the elements from a donor substrate to the display substrate.

15. A method according to claim 14 wherein the plurality of semiconductor elements on the donor substrate are reversibly bonded to an elastomeric stamp and transferred to the display substrate.

16. A backplane for use in a display device as claimed in claim 1, the backplane comprising a substrate having a surface comprising a plurality of semiconductor elements and a plurality of color filters and/or downconverters on the same surface.
